(19) United States
(12) Patent Application Publication
(10) Pub. No.: US 2026/0173687 A1
(43) Pub. Date: Jun. 18, 2026

(54) Display Apparatus

(71) Applicant: LG Display Co., Ltd., Seoul (KR)

(72) Inventor: Beom Jeong, Paju-si (KR)

(21) Appl. No.: 19/371,816

(22) Filed: Oct. 28, 2025

(30) Foreign Application Priority Data
Dec. 17, 2024 (KR) 10-2024-0188780

(51) Int. Cl. H10K 59/131

(52) U.S. Cl. CPC H10K 59/131

(57) ABSTRACT

The present disclosure provide a display apparatus including a display panel including a display area and a non-display area, and a driving chip disposed in the non-display area, wherein a first wiring part around the driving chip comprises a substrate, a first metal wiring layer on the substrate, a buffer layer on the first metal wiring layer, a GIP wiring on the buffer layer, a gate insulating layer on the GIP wiring, a second metal wiring layer on the gate insulating layer, and an interlayer insulating layer on the second metal wiring layer.

### CROSS-REFERENCE TO RELATED APPLICATION

This application claims the benefit of priority of the Republic of Korea Patent Application No. 10-2024-0188780 filed on December 17, 2024, which is hereby incorporated by reference in its entirety.

### BACKGROUND

### Field of Technology

The present disclosure relates to a display apparatus, and more particularly, to a display apparatus capable of improving reliability.

### Discussion of the Related Art

As we enter the information age, the field of display apparatuses that visually display electrical information signals is rapidly developing, and research is ongoing to develop performances such as thinning, weight reduction, and low power consumption for various display apparatuses.

Recently, various display apparatuses such as liquid crystal display apparatus (LCD), field emission display apparatus (FED), and organic light emitting display apparatus (OLED) are being utilized.

### SUMMARY

The present disclosure provides a display apparatus that can improve reliability by protecting gate-in panel (GIP) wiring from moisture infiltration due to cracks around a driving chip and corrosion failure of pads or wiring.

The present disclosure provides a display apparatus that can prevents screen abnormality by preventing a short circuit in a GIP line caused by cracks occurring around a driving chip due to stress concentration when mounting a driving chip on a display panel.

The present disclosure provides a display apparatus capable of improving reliability degradation of the display apparatus due to cracks.

A display apparatus according to an embodiment of the present disclosure may include a display panel having a display area and a non-display area, and a driving chip disposed in the non-display area, wherein a first wiring part around the driving chip may include a substrate, a first metal wiring disposed on the substrate, a buffer layer disposed on the first metal wiring, a GIP wiring disposed on the buffer layer, a gate insulating layer disposed on the GIP wiring, a second metal wiring disposed on the gate insulating layer, and an interlayer insulating layer disposed on the second metal wiring.

The GIP wiring may include molybdenum (Mo), which is the same material as the gate electrode, but is not limited thereto.

The first metal wiring and the second metal wiring may be floating metals and may be formed of either molybdenum (Mo) or aluminum (Al), but are not limited thereto.

The GIP wiring may be disposed between the first metal wiring and the second metal wiring.

The first metal wiring may be disposed below the GIP wiring. The second metal wiring may be disposed above the GIP wiring.

The first metal wiring layer may be disposed on a same layer as a light shielding layer wiring of the display area under the GIP wiring.

Each of the first metal wiring and the second metal wiring may have a wiring width greater than or equal to that of the GIP wiring.

Each of the first metal wiring and the second metal wiring may be formed in a separated structure similar to the GIP wiring.

The GIP wiring may be formed in a separated structure from each other.

The first metal wiring layer, the second metal wiring layer and the GIP wiring may be spaced apart from each other.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plan view of a display apparatus according to one embodiment.

FIG. 2 is a circuit diagram of a sub pixel according to one embodiment.

FIG. 3 is an enlarged partial plan view of part A of FIG. 1.

FIG. 4 is a cross-sectional view taken along line I-I' of FIG. 3.

FIG. 5 is a cross-sectional view taken along line A-A' of FIG. 3.

FIG. 6 is a drawing of a case where a crack occurs when one embodiment is applied.

### DETAILED DESCRIPTION

Hereinafter, embodiments will be described with reference to the drawings.

The identical drawing symbols indicate identical components. Additionally, in the drawings, the thicknesses, proportions, and dimensions of components may be exaggerated to effectively illustrate the technical content. The scale of the components shown in the drawings is different from the actual scale for convenience of explanation, and is not limited to the scale shown in the drawings.

In this disclosure, when it is said that a component or region, layer, portion, etc. is “on,” “connected to,” or “coupled to” another component, it means that it may be directly connected/coupled to the other component, or a third component may be disposed between them.

“And/or” includes any combination of one or more of the associated constructs that may be defined.

While terms such as "first" and "second" may be used to describe various components, these components are not limited by these terms. These terms are used solely to distinguish one component from another. For example, without departing from the scope of the present embodiments, a "first" component may be referred to as a "second" component, and similarly, a "second" component may also be referred to as a "first" component. Singular expressions include plural expressions unless the context clearly indicates otherwise.

The terms such as "below," "beneath," "above," and "upper" are used to describe the relationships between components depicted in the drawings. These terms are relative concepts and are described based on the directions indicated in the drawings. For example, one or more other components may be located between two components unless "directly" or "directly" is used. Spatially relative terms such as "below," "beneath," "lower," "above," and "upper" may be used to easily describe the relationship between one element or component and another element or component as depicted in the drawings. Spatially relative terms should be understood to include different orientations of elements during use or operation in addition to the orientations depicted in the drawings. For example, if an element depicted in a drawing is turned over, an element described as "below" or "beneath" another element may actually be located "above" the other element. Thus, the exemplary term "below" can encompass both downward and upward directions.

The terms such as "include" or "have" should be understood to specify the presence of a feature, number, step, operation, component, part or combination thereof described in the disclosure, but not to exclude in advance the possibility of the presence or addition of one or more other features, numbers, steps, operations, components, parts or combinations thereof.

The individual features of the various embodiments of this disclosure may be partially or wholly combined or combined with each other, and may be technically linked and operated in various ways, and each embodiment may be implemented independently of each other or may be implemented together in a related relationship.

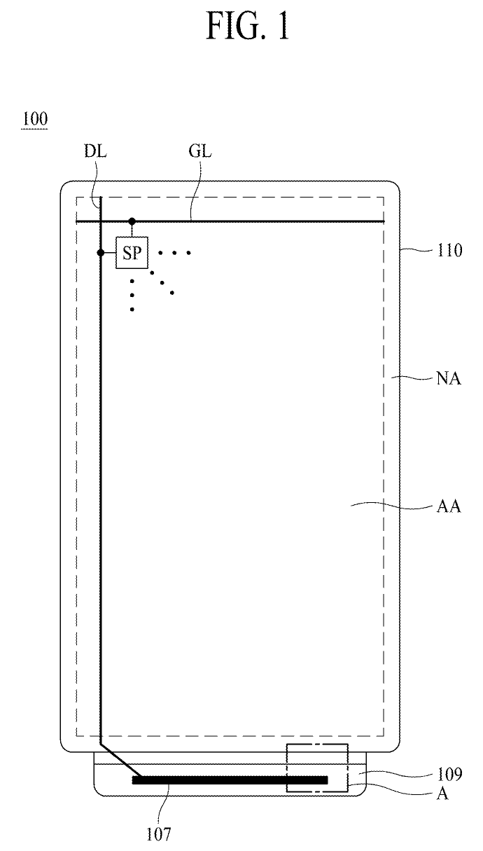

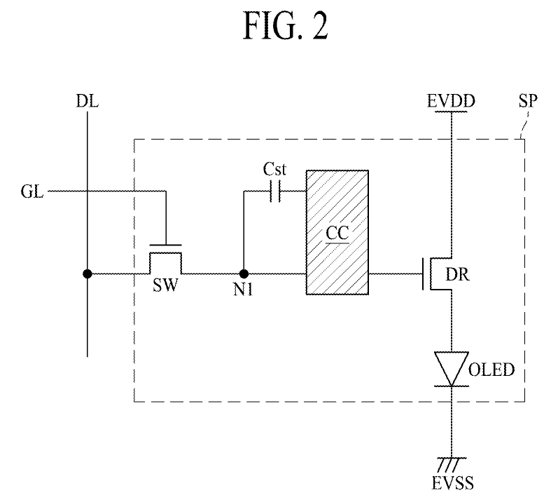

Hereinafter, the display apparatus of the present disclosure will be examined through the attached drawings and embodiments. FIG. 1 is a plan view of a display apparatus according to one embodiment, and FIG. 2 is a circuit diagram of a sub pixel according to one embodiment.

Referring to FIG. 1 and FIG. 2, a display apparatus 100 according to an example of the present disclosure includes a display panel 110 including a display area AA and a non-display area NA, and a driving chip 107 disposed in the non-display area NA of the display panel 110. The driving chip 107 may be disposed in a driving circuit area 109 of the non-display area NA.

The display area AA is an area where an image is displayed. A plurality of sub pixels SP are disposed in the display area AA of the display panel 110, and an image may be displayed using the plurality of sub pixels SP. The area where the plurality of sub pixels SP are disposed becomes the display area AA, and an area other than the display area AA may become a non-display area NA. At least a portion of the non-display area NA may be bent to be invisible from the front surface of the display apparatus 100 or may be covered by a case or housing (not shown) of the display apparatus 100. The non-display area NA may be also referred to as an edge area or a bezel area.

Referring to FIG. 2, at least one sub pixel SP among a plurality of pixels may include a switching transistor SW, a driving transistor DR, a capacitor Cst, a compensation circuit CC, and an organic light emitting diode OLED, and may include more or less elements. The sub pixel SP can be composed of 3T1C, 4T1C, 5T1C, 6T1C, 7T1C, 3T2C, 4T2C, 5T2C, 6T2C, 7T2C, 8T2C, etc.

A first electrode (e.g., a drain electrode) of a switching transistor SW is electrically connected to a data line DL, and a second electrode (e.g., a source electrode) is electrically connected to a first node N1. A gate electrode of the switching transistor SW is electrically connected to a gate line GL. The switching transistor SW transmits a data signal supplied through a data line DL to the first node N1 in response to a scan signal supplied through the gate line GL. For example, when the switching transistor SW is turned on in response to a scan signal supplied through the gate line GL, the data signal supplied through a data line DL can be transmitted to the first node N1 of the driving transistor DR.

The capacitor Cst is electrically connected to the first node N1 and charges the voltage applied to the first node N1.

The first electrode (e.g., a drain electrode) of a driving transistor DR is applied with a high-potential driving voltage EVDD, and a second electrode (e.g., a source electrode) is electrically connected to a first electrode (e.g., an anode electrode) of an organic light emitting diode OLED. The driving transistor DR can control the amount of driving current flowing in the organic light emitting diode OLED in response to the voltage applied to the gate electrode.

The semiconductor layer of the switching transistor SW and/or the driving transistor DR may include silicon such as amorphous silicon (a-Si), polycrystalline silicon (poly-Si), or low-temperature polycrystalline silicon (poly-Si), or may include an oxide such as indium-gallium-zinc-oxide (IGZO), but is not limited thereto.

The organic light emitting diodes OLED emit light corresponding to the driving current. The organic light emitting diode may emit light corresponding to any one of the colors red, green, blue, and white, but is not limited thereto. In another exemplary embodiment, organic light emitting diode may emit one color among cyan, magenta and yellow. In various embodiments, organic light emitting diode may emit one color among red, green and blue.

The organic light emitting diode OLED may include an anode electrode, a light emitting layer disposed on the anode electrode, and a cathode electrode that supplies a common voltage. The light emitting layer may be implemented to emit light of the same color for each pixel, such as white light, or may be implemented to emit different colors for each sub pixel SP, such as red, green, or blue light. For example, the light emitting layer may include one or more of a hole injection layer (HIL), a hole transmitting layer (HTL), an electron transmitting layer (ETL) and an electron injection layer (EIL), but the present disclosure is not limited thereto.

The organic light emitting diodes OLEDs may be either top-emitting or bottom-emitting.

The compensation circuit CC may be provided within a sub pixel SP to compensate for the threshold voltage of a driving transistor DR, etc. The compensation circuit CC may be composed of one or more transistors. The compensation circuit CC may include one or more transistors and a capacitor, and may be configured in various ways depending on the compensation method. A pixel including a compensation circuit CC may have various structures, such as 3T1C, 4T2C, 5T2C, 6T1C, 6T2C, 7T1C, and 7T2C.

The non-display area NA may be formed in an edge area surrounding the display area AA that displays an image, as illustrated in FIG. 1. The non-display area NA includes a driving circuit area 109 for driving a plurality of sub pixels SP, and at least one driving chip 107 may be disposed in the driving circuit area 109. The driving chip 107 may be in the form of a driving integrated circuit (D-IC). The driving chip 107 may be mounted in the non-display area NA of the display panel 110 in a chip-on-panel (COP) method. The driving chip 107 may function as a data driving circuit.

The driving circuit area 109 may further include a gate driving circuit (not shown) disposed in a non-display area NA in the form of a gate-in-panel GIP, without being limited thereto. Alternatively, the gate driving circuit may be disposed in the display area AA of the display panel. The gate driving circuit may be a circuit for driving a plurality of gate lines, and can supply gate signals to the plurality of gate lines. In one or more aspects, at least one of the data driving circuit and the gate driving circuit may be disposed in the display area AA of the display panel.

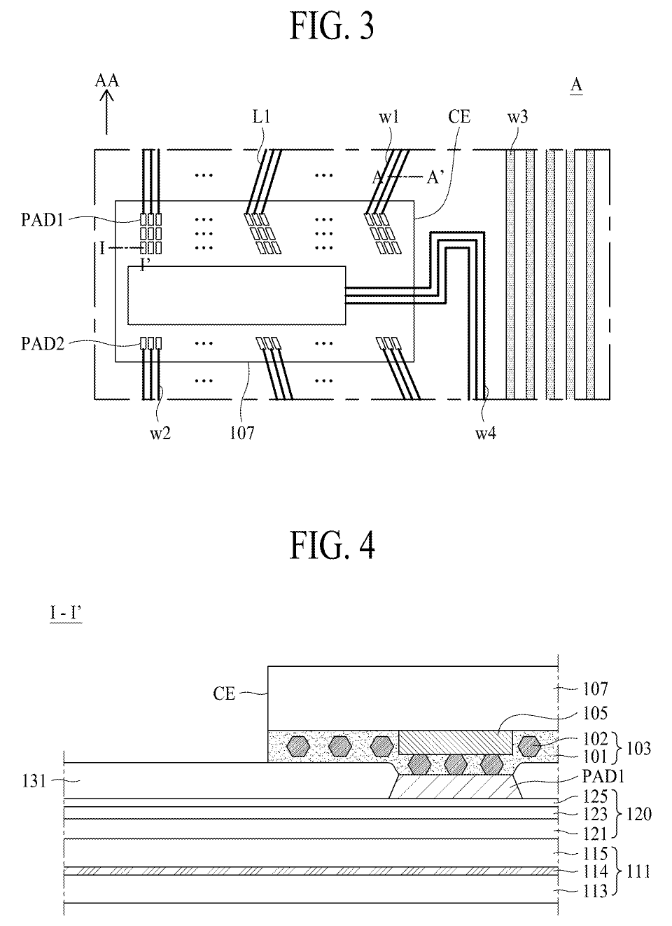

FIG. 3 is an enlarged partial plan view of part A of FIG. 1.

Referring to FIG. 1 and FIG. 3, the display panel 110 may further include a first pad PAD1, a second pad PAD2 electrically connected to a driving chip 107 disposed in a non-display area NA, and a plurality of wires W1, W2, L1 disposed in the non-display area NA and electrically connected to the pads PAD1, PAD2.

The driving chip 107 may be disposed in the non-display area NA of the display panel 110 in a chip on panel (COP) method, but is not limited thereto. The COP method is a method of directly attaching the drive IC onto pads of a substrate using an anisotropic conductive film (ACF).

The driving chip 107 receives signals required for driving the display panel 110 from the outside and provides or transmits the signals to the display panel 110. The driving chip 107 may be a source driver integrated circuit that provides a data signal to a data line DL of the display area AA, but is not limited thereto.

The driving chip 107 is electrically connected to the display panel 110 through the second pad PAD2 and the first pad PAD1. The driving chip 107 receives a signal from the outside through the second wiring W2 and the second pad PAD2. The driving chip 107 may provide the signal received from the outside to the display area AA through the first pad PAD1, the first wiring W1, and the link line L1.

The first pad PAD1 is disposed relatively closer to the display area AA than the second pad PAD2, but is not limited thereto.

The first pad PAD1 may be disposed in multiple rows. A plurality of first pads PAD1 disposed in one row are spaced apart from each other. The first pads PAD1 are illustrated as being disposed in three rows, but is not limited thereto, and may be disposed in two or fewer rows, or in four or more rows. The first pad PAD1 may have a short side and a long side. For example, each of the plurality of first pads PAD1 may have a short side and a long side, but is not limited thereto. The short side of the first pad PAD1 may be in a direction perpendicular to the long side of the driving chip 107.

The first pad PAD1 is connected to link lines L1 and first wires W1. Each of the plurality of first pads PAD1 may be connected one-to-one to each of the link lines L1 and the first wires W1, but is not limited thereto. The link lines L1 may be connected to data lines DL of the display area AA.

The first pad PAD1 may be disposed on the same layer as any one of a plurality of adjacent wires, for example, the first wiring W1, the third wiring W3, the link lines L1, and the fourth wiring W1, but is not limited thereto. The first pad PAD1 may be made of the same material as any one of a plurality of adjacent wires, for example, the first wiring W1, the third wiring W3, the link lines L1, and the fourth wiring W1, but is not limited thereto. For example, the first pad PAD1 may be made of the material different from that of any one of a plurality of adjacent wires, for example, the first wiring W1, the third wiring W3, the link lines L1, and the fourth wiring W1.

The first pad PAD1 may be disposed on the same layer as the second wiring W2 that is electrically connected to the second pad PAD located opposite thereto, but is not limited thereto. The first pad PAD1 may be made of the same material as the second wiring W2, but is not limited thereto. For example, the first pad PAD1 may be made of the material different from that of the second wiring W2.

The first pad PAD1 is connected to the driving chip 107 through an anisotropic conductive film, but is not limited thereto. At this time, the bumps disposed on the driving chip 107 and the first pad PAD1 are electrically connected. Each of the first pads PAD1 may be connected to the bumps one-to-one. Accordingly, the first pad PAD1 can receive voltages and signals applied to the driving chip 107 through the bumps.

The second pad PAD2 may be disposed in a single row. A plurality of second pads PAD2 disposed in a single row are spaced apart from each other. The second pads PAD2 are illustrated as being disposed in one row, but are not limited thereto and may be disposed in two or more rows. The second pad PAD2 may have a short side and a long side. For example, each of the plurality of second pad s PAD2 may have a short side and a long side, but is not limited thereto. The short side of the second pad PAD2 may be in a direction perpendicular to the long side of the driving chip 107.

The second pad PAD2 is connected to the second wires W2. Each of the plurality of second pads PAD2 may be connected one-to-one to each of the second wires W2, but is not limited thereto. The second wires W2 may be connected to an external circuit board (not shown).

The second pad PAD2 may be disposed on the same layer as the second wiring W2 to which it is electrically connected. The second pad PAD2 may be made of the same material as the second wiring W2, but is not limited thereto. For example, the second pad PAD2 may be made of the material different from that of the second wiring W2. The second pad PAD2 may be disposed on the same layer as any one of a plurality of wirings adjacent to the first pad PAD1 located opposite thereto, for example, the first wiring W1, the third wiring W3, the link lines L1, and the fourth wiring W4. The second pad PAD2 may be made of the same material as any one of the first wiring W1, the third wiring W3, the link lines L1, and the fourth wiring W4, but is not limited thereto.

The second pad PAD2 is connected to the driving chip 107 through an anisotropic conductive film 103, but is not limited thereto. At this time, the bumps disposed on the driving chip 107 and the second pad PAD2 are electrically connected. Each of the second pads PAD2 may be connected to the bumps one-to-one. For example, one second pads PAD2 may be connected to one bump. Accordingly, the second pad PAD2 may provide external voltages and signals to the driving chip 107 through the bumps.

The structures of the first pad PAD1 and the second pad PAD2 may be substantially identical.

The first wiring W1 can connect the first pad PAD1 and some of the signal lines (e.g., gate line, GL). The first wiring W1 may be a gate control line.

The link line L1 can connect the first pad PAD1 and some of the signal lines (e.g., data line, DL).

The first wiring W1 and the link line L1 may be disposed on the same layer. The first wiring W1 and the link line L1 may be made of the same material, but is not limited thereto.

The first wiring W1 and the link line L1 may be disposed in a direction intersecting the long side of the driving chip 107. The first wiring W1 and the link line L1 may form a certain angle with the long side of the driving chip 107, but is not limited thereto.

The second wiring W2 is disposed at one end of the display panel 110 and connects the second pad PAD2 and an external circuit board (not shown). For example, the external circuit board may be a flexible printed circuit board FPC. The second wiring W2 may be disposed in a direction intersecting the long side of the driving chip 107.

The second wiring W2 and the link line L1 may be disposed on the same layer. The second wiring W2 and the link line L1 may be made of the same material.

The display panel 110 may further include a third wiring W3 and a fourth wiring W4 disposed in a non-display area NA around the driving chip 107.

The third wiring W3 may be disposed in a direction parallel to the short side of the driving chip 107 without electrical connection with the driving chip 107. The third wiring W3 may be a power wiring. For example, the third wiring W3 may be disposed in a direction intersecting the long side of the driving chip 107.

The third wiring W3 may be disposed on the same layer as the first wiring W1. The third wiring W3 and the first wiring W1 may be made of the same material. However, the present disclosure is not limited thereto. For example, the third wiring W3 may be made of a material different from that of the first wiring W1. The third wiring W3 may be disposed on the same layer as the link line L1. The third wiring W3 and the link line L1 may be made of the same material. However, the present disclosure is not limited thereto. For example, the third wiring W3 may be made of a material different from that of the link line L1.

The third wiring W3 may be disposed on the same layer as the second wiring W2. The third wiring W3 and the second wiring W2 may be made of the same material. However, the present disclosure is not limited thereto. For example, the third wiring W3 may be made of a material different from that of the second wiring W2.The third wiring W3 may be disposed on the same layer as the fourth wiring W4. The third wiring W3 and the fourth wiring W4 may be made of the same material. However, the present disclosure is not limited thereto. For example, the third wiring W3 may be made of a material different from that of the fourth wiring W4.

The fourth wiring W4 may be disposed in a direction intersecting the short side of the driving chip 107. For example, a portion of the fourth wiring W4 may be disposed in a direction intersecting the short side of the driving chip 107, and another portion of the fourth wiring W4 may be disposed in a direction parallel to the third wiring W3, but is not limited thereto. The fourth wiring W4 may be a multiplexer driving line or a test line.

The fourth wiring W4 may be disposed on the same layer as the first wiring W1. The fourth wiring W4 and the first wiring W1 may be made of the same material. The fourth wiring W4 may be disposed on the same layer as the link line L1. The fourth wiring W4 and the link line L1 may be made of the same material. However, the present disclosure is not limited thereto.

The fourth wiring W4 may be disposed on the same layer as the second wiring W2. The fourth wiring W4 and the second wiring W2 may be made of the same material. The fourth wiring W4 may be disposed on the same layer as the third wiring W3. The fourth wiring W4 and the third wiring W3 may be made of the same material. However, the present disclosure is not limited thereto.

As explained above, the driving chip 107 is attached to the substrate 111 as a source drive IC using the COP method, so a pressure mark inspection, etc. is performed to check the connection status of the driving chip 107, and high pressure must be applied when attaching the driving chip 107 to the substrate 111 to prevent poor connection of the driving chip 107.

The GIP wiring section according to this disclosure can protect the GIP wiring from moisture infiltration due to cracks around the driving chip and corrosion failure of the pad or wiring by arranging the first and second metal wiring layers on the lower portion and upper portion of the GIP wiring.

The first and second metal wiring layers disposed on the upper and lower portions of the GIP wiring according to the present disclosure have a wiring width that is greater than or equal to the GIP wiring, and even if a crack occurs due to the space between the metal wiring layers, the first and second metal wiring layers disposed on the upper and lower portions of the GIP wiring are primarily prevented from oxidation, and the oxidation and dissolution of the floating metal wiring layer proceed first, so that the GIP wiring may be protected from moisture penetration due to cracks around the driving chip and from corrosion failure of the pad or wiring.

FIG. 4 is a cross-sectional view taken along line I-I' of FIG. 3.

Referring to FIG. 4, the display panel 110 (shown in FIG. 1) includes a substrate 111. An insulating layer 120 may be disposed in a non-display area NA on the substrate 111, and a planarization layer131 may be disposed on the insulating layer 120. For example, the planarization layer 131 may be disposed on a portion of the insulating layer 120.

A plurality of insulating layers 120 may be laminated and disposed in a non-display area NA on a substrate 111. The insulating layer 120 may include a buffer layer 121, a gate insulating layer 123, and an interlayer insulating layer 125. For example, the buffer layer 121 may be disposed on the substrate 111, and the gate insulating layer 123 may be disposed between the buffer layer 121 and the interlayer insulating layer 125.

The substrate 111 may be formed of a flexible plastic material and thus may have flexible characteristic. The substrate 111 may be formed by including polyimide and may include a thin, flexible glass material.

The substrate 111 may include a support substrate such as PET (polyethylene terephthalate), a polyimide film, and an adhesive film such as PSA (pressure sensitive adhesive) for bonding the PET and polyimide films.

The substrate 111 may include a first substrate 113, a second substrate 115, and an intermediate layer 114 disposed between the first substrate 113 and the second substrate 115. The intermediate layer 114 may include an adhesive material. The intermediate layer 114 may include an insulating material such as silicon nitride or silicon oxide, but is not limited thereto.

On the substrate 111, a plurality of sub pixels SP may be disposed in a display area AA as shown in FIG. 1, and a driving chip 107 may be disposed in a non-display area NA.

The buffer layer 121 is disposed on the substrate 111. The buffer layer 121 is disposed on the substrate 111 to protect thin film transistors and light emitting elements disposed in the display area AA from moisture penetrating through the substrate 111. The buffer layer 121 is disposed to overlap the driving chip 107 of the non-display area AA to prevent moisture from penetrating from the edge of the substrate 111.

The buffer layer 121 may be formed of a plurality of inorganic films alternately laminated, but is not limited thereto. For example, the buffer layer 121 may be formed of an inorganic film in a single layer. For example, the buffer layer 121 may include a multi-film in which one or more inorganic films of a silicon oxide film (SiOx), a silicon nitride film (SiNx), and a silicon oxynitride film (SiOxNy) are alternately laminated. For example, the inorganic film in a single layer may be a silicon oxide (SiO) film or a silicon nitride (SiN) film.

The gate insulating layer 123 is disposed on the buffer layer 121. The gate insulating layer 123 is disposed in the display area AA illustrated in FIG. 1 and FIG. 2 to prevent short circuits between electrodes constituting the thin film transistors. The gate insulating layer 123 is disposed to extend to the non-display area NA to prevent short circuits between electrodes constituting the thin film transistors disposed in the non-display area NA. The gate insulating layer 123 may be disposed to overlap with the driving chip 107 of the non-display area NA.

For example, the gate insulating layer 123 may be composed of a single layer or multilayers of inorganic films. The gate insulating layer 123 may include an inorganic film, for example, a silicon oxide film (SiOx), a silicon nitride film (SiNx), or a multi-layer thereof.

The interlayer insulating layer 125 may be disposed on the gate insulating layer 123. The interlayer insulating layer 125 is disposed in the display area AA illustrated in FIG. 1 and FIG. 2 to electrically insulate electrodes disposed vertically that constitute thin film transistors. The interlayer insulating layer 125 may extend to the non-display area NA to electrically insulate electrodes disposed vertically that constitute thin film transistors disposed in the non-display area NA. The interlayer insulating layer 125 may be disposed to overlap with the driving chip 107 of the non-display area NA.

The interlayer insulating layer 125 may include an inorganic material. The inorganic material may include, for example, silicon nitride, silicon oxynitride, and silicon oxide. Alternatively, the interlayer insulating layer 125 may be arranged to include a multilayer thereof.

The first pad PAD1 may be disposed on a plurality of insulating layers 120. For example, the first pad PAD1 may be disposed to cover a portion of the interlayer insulating layer 125 of the insulating layers 120.

The first pad PAD1 may be formed by including a metal layer.

The planarization layer 131 is disposed on the first pad PAD1. The planarization layer 131 may be disposed so as to extend to the side of the first pad PAD1 so as to cover the insulating layer 120 and the side of the first pad PAD1. For example, the planarization layer 131 may be disposed to cover an upper surface of the interlayer insulating layer 125 of the insulating layers 120 and the side of the first pad PAD1.

The planarization layer 131 may be disposed to overlap with one short edge CE of the driving chip 107. At this time, one short edge CE of the driving chip 107 may overlap with the planarization layer 131. For example, the driving chip 107 may overlap with the first pad PAD1 and a portion of the planarization layer 131.

The planarization layer 131 may include an organic material. The organic material may include at least one of an acrylic resin, an epoxy resin, a phenolic resin, a polyamide resin, and a polyimide resin, but is not limited thereto.

In addition to the insulating layer 120 described above, various organic or inorganic films may be further arranged between the substrate 111 and the planarization layer 131.

The driving chip 107 may include a bump 105 corresponding to the first pad PAD1. A plurality of bumps 105 may be disposed to face pads disposed in the non-display area NA, such as the first pad PAD1. For example, the bump 105 of the driving chip 107 may overlap with the first pad PAD1.

The anisotropic conductive film 103 is disposed between the driving chip 107 and the pad PAD1.

The anisotropic conductive film 103 includes an adhesive member 101 and a plurality of conductive balls 102. The adhesive member 101 allows the driving chip 107 to be attached to the display panel 110, and the conductive balls 102 are irregularly distributed within the adhesive member 101 to allow the driving chip 107 to be electrically connected to the first pad PAD1.

The conductive ball 102 may be a conductive particle itself, a particle coated with a metal layer on a polymer resin particle, or a particle coated with an insulating resin on the surface of the conductive particle or particle coated with a metal layer. For example, the metal layer may be made of a material such as nickel (Ni), gold (Au), or the like. However, the present disclosure is not limited thereto.

The anisotropic conductive film 103 may be disposed to overlap with the edge portion of the planarization layer 131 that is arranged to overlap with the edge CE of the driving chip 107.

Since the driving chip 107 is electrically connected to the first pad PAD1 through the conductive ball 102, pressure is applied when mounting the driving chip 107 so that the conductive ball 102 comes into contact with the bump 105 and the first pad PAD1. FIG. 4 is a cross-sectional view taken along line I-I' of FIG. 3.

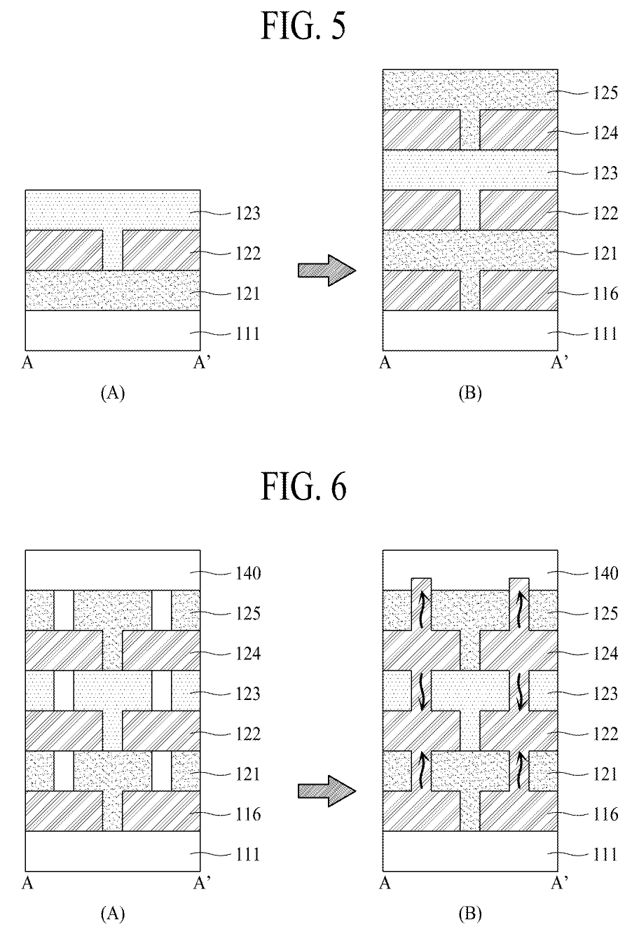

FIG. 5A and FIG. 5B are cross-sectional views taken along line A-A' of FIG. 3.

FIG. 5A and FIG. 5B are cross-sectional views of a first wiring structure B of an embodiment in which a metal wiring layer is disposed above and below the GIP wiring, compared to the existing first wiring structure A, to prevent the GIP wiring from being disconnected due to cracks occurring around the driving chip in a high temperature and high humidity reliability environment after the COP process of bonding the driving chip to the display panel.

Referring to FIG. 5A is a conventional first wiring structure in which no metal wiring layer is disposed on the upper and lower portions of the GIP wiring, and FIG. 5B is a first wiring structure according to an embodiment of the present disclosure in which a metal wiring layer is disposed on the upper and lower portions of the GIP wiring, thereby preventing disconnection of the GIP wiring even if a crack occurs in the periphery of the driving chip. For example, the first metal wiring layer 116 may be disposed below the GIP wiring 122, and the second metal wiring layer 124 may be disposed above the GIP wiring 122.

Referring to FIG. 5A, the existing first wiring W1 structure is a structure in which a buffer layer 121 is disposed on a substrate 111, a GIP wiring 122 is disposed on the buffer layer 121, and a gate insulating layer 123 is disposed on the GIP wiring 122, and it cannot prevent the GIP wiring from being disconnected due to cracks occurring around the driving chip in a high temperature and high humidity reliability environment after the COP process of bonding the driving chip to the display panel.

Referring to FIG. 5B, the first wiring W1 structure of the embodiment of the present disclosure is a structure in which a first metal wiring layer 116 is disposed on a substrate 111, a buffer layer 121 is disposed on the first metal wiring layer 116, a GIP wiring 122 is disposed on the buffer layer 121, a gate insulating layer 123 is disposed on the GIP wiring 122, a second metal wiring layer 124 is disposed on the gate insulating layer 123, and an interlayer insulating layer 125 is disposed on the second metal wiring layer 124, and the GIP wiring may be prevented from being disconnected due to cracks occurring in the periphery of the driving chip in a high temperature and high humidity reliability environment after the COP process of bonding the driving chip to the display panel.

Referring to FIG. 5B, the first and second metal wiring layers 116, 124 disposed at the upper and lower portions to protect the GIP wiring 122 are not in the form of a single plate, but have a wiring width that is greater than or equal to the GIP wiring 122, and a space may exist between each wiring layer. For example, the first and second metal wiring layers 116, 124 may have a wiring width greater than or equal to that of the GIP wiring 122.

The first and second metal wiring layers 116, 124 are in an electrically floating state.

The first and second metal wiring layers 116, 124 may be made of both Mo and AL and may be overlapped with all metal layers used in TFT and TOE, and no mask is added.

To prevent mask addition, the first metal wiring layer 116, which is the lower floating wiring, uses the light shielding layer wiring under the GIP wiring, and the second metal wiring layer 124, which is the upper floating wiring, may use any metal under the touch interlayer insulating layer, which is the top layer of the corresponding area. For example, the second metal wiring layer 24 may be any one of a dummy metal layer TM1, a gate metal layer O-GATE of the oxide transistor, a first source/drain metal layer SD1, a second source/drain metal layer SD2, and a touch electrode metal layer TOE TM1).

FIG. 6 is a drawing of a case where a crack occurs when one embodiment is applied.

FIG. 6A is a drawing for explaining a case where a crack occurs in a film. When a stress is concentrated and a crack occurs around the driving chip when the driving chip is mounted on a display panel, a gap due to the crack may be formed in the buffer layer 121 between the GIP wiring 122 and the first metal wiring layer 116, a gap due to the crack may be formed in the gate insulating layer 123 between the GIP wiring 122 and the second metal wiring layer 124, and a gap due to the crack may be formed in the interlayer insulating layer 125 between the second metal wiring layer 124 and the ACF 140.

FIG. 6B is a drawing for explaining the oxidation and dissolution of the first and second metal wiring layers 116, 124 after a crack occurs in the inorganic film. Even if a crack occurs in the inorganic film in a reliable environment, the first and second metal wiring layers 116 and 124, which are floating wirings disposed on the upper and lower portions of the GIP wiring 122, primarily prevent oxidation, and the oxidation and dissolution of the first and second metal wiring layers 116 and 124 on the upper and lower portions of the GIP wiring 122 first proceed into the gap formed in the buffer layer 121, the gate insulating layer 123, and the interlayer insulating layer 125, thereby preventing the oxidation and dissolution of the GIP wiring 122. In addition, even if a crack occurs in the GIP wiring 122 and a short circuit occurs between the first and second metal wiring layers 116, 124, which are floating wiring, the GIP wiring 122 can operate normally because the GIP wiring 122 is separated from each other.

The GIP wiring of the display apparatus according to this disclosure may provide a display apparatus with improved reliability by arranging first and second metal wiring layers on the upper and lower portions of the GIP wiring to protect the GIP wiring from moisture infiltration due to cracks around the driving chip and corrosion failure of the pad or wiring.

The first and second metal wiring layers, which are floating wirings disposed above and below the GIP wiring of the display apparatus according to the present disclosure, are larger than or equal to the GIP wiring, and the first and second metal wiring layers disposed above and below the GIP wiring primarily prevent oxidation, and the oxidation and dissolution of the first and second metal wiring layers, which are floating wirings, proceed first, thereby protecting the GIP wiring from moisture penetration due to cracks around the driving chip and corrosion failure of the pad or wiring, thereby improving the reliability of the display apparatus may be provided.

The display apparatus according to this disclosure can minimize the occurrence of defects in the display apparatus by utilizing the same process, thereby reducing production energy for producing the display apparatus and reducing the use of hazardous production materials or regulated substances, which is advantageous for recycling and can lead to the implementation of an eco-friendly display apparatus.

The display device according to the present disclosure can improve reliability by disposing first and second metal wiring layers above and below the GIP wiring so as to protect the GIP wiring from moisture penetration due to cracks around the driving chip and from corrosion defects of pads or wirings.

The first and second metal wiring layers, which are floating wirings disposed above and below the GIP wiring of the display device according to the present disclosure, may have a wiring width greater than or equal to that of the GIP wiring. The first and second metal wiring layers disposed above and below the GIP wiring may primarily prevent oxidation, and oxidation and dissolution of the floating wirings, i.e., the first and second metal wiring layers, may occur first, thereby protecting the GIP wiring from moisture penetration due to cracks around the driving chip and from corrosion defects of pads or wirings, and thus providing a display device with improved reliability.

The display device according to the present specification may minimize occurrence of defects in the display device by utilizing the same process, thereby reducing production energy required for manufacturing the display device, and may reduce the use of harmful production materials or regulated substances, thereby being advantageous for recycling and enabling implementation of an environmentally friendly display device.

Although the above description focuses on embodiments, these are merely examples and do not limit the present disclosure. The present disclosure described above is not limited to the aforementioned embodiments and the attached drawings, and the features, structures, effects, etc. exemplified in each embodiment may be implemented by combining or modifying them. Therefore, the contents related to such combinations and modifications should be interpreted as being included within the scope of the present disclosure.

What is claimed is:

1. A display apparatus comprising:
a display panel including a display area and a non-display area; and
a driving chip disposed in the non-display area,
wherein a first wiring part around the driving chip comprises:
a substrate;
a first metal wiring layer on the substrate;
a buffer layer on the first metal wiring layer;
a gate-in panel (GIP) wiring on the buffer layer;
a gate insulating layer on the GIP wiring;
a second metal wiring layer on the gate insulating layer; and
an interlayer insulating layer on the second metal wiring layer.

2. The display apparatus of claim 1,
wherein the GIP wiring is disposed between the first metal wiring layer and the second metal wiring layer.

3. The display apparatus of claim 1,
wherein the first metal wiring layer and second metal wiring layer are in an electrically floating state.

4. The display apparatus of claim 1,
wherein the first metal wiring layer and the second metal wiring layer include molybdenum Mo or aluminum Al.

5. The display apparatus of claim 1,
wherein the first metal wiring layer is disposed on a same layer as a light shielding layer wiring of the display area under the GIP wiring.

6. The display apparatus of claim 1,
wherein the GIP wiring includes molybdenum Mo.

7. The display apparatus of claim 1,
wherein the first metal wiring layer and second metal wiring layer have a wiring width greater than or equal to that of the GIP wiring.

8. The display apparatus of claim 1,
wherein the GIP wiring is formed in a separated structure from each other.

9. The display apparatus of claim 1, wherein the first metal wiring layer, the second metal wiring layer and the GIP wiring are spaced apart from each other.
